(19) United States
(12) Patent Application Publication
(10) Pub. No.: US 2016/0282659 A1
(43) Pub. Date: Sep. 29, 2016

(54) ARRAY SUBSTRATE, METHOD FOR FABRICATING THE SAME, AND DISPLAY APPARATUS

(71) Applicants: BOE TECHNOLOGY GROUP CO., LTD., Beijing (CN); HEFEI BOE OPTOELECTRONICS TECHNOLOGY CO., LTD., Hefei, Anhui Province (CN)

(72) Inventors: Qiangqiang Luo, Beijing (CN); Kiyoung Kwon, Beijing (CN); Baoquan Zhou, Beijing (CN); Kun Qu, Beijing (CN); Zhenfang Li, Beijing (CN)

(21) Appl. No.: 14/408,289

(22) PCT Filed: Jun. 5, 2014
(86) PCT No.: PCT/CN2014/000562

§ 371 Date: Dec. 15, 2014

(30) Foreign Application Priority Data
Dec. 20, 2013 (CN) 201310712539.5

(51) Int. Cl. G02F 1/1345; H01L 23/00; H01L 27/12; H01L 25/065; G02F 1/1333; G02F 1/1341

(52) U.S. Cl. CPC G02F 1/13452; G02F 1/133345; G02F 1/1341; H01L 27/124; H01L 27/1259; H01L 25/0657; H01L 24/32; H01L 2224/32145; H01L 2924/1426; H01L 2224/29344

(57) ABSTRACT

The present invention discloses an array substrate, a method for fabricating the same, and a display apparatus. The array substrate is provided with a plurality of signal lines in a peripheral area, at least two adhesion layers of different thicknesses are provided at positions of each signal line where the signal lines are connected with a driving IC chip, and said adhesion layers are electrically connected via a conductive metal layer. The adhesion layer is designed to have at least two adhesion layers, instead of a single layer in the prior art. Two adhesion layers with different thicknesses are provided at a bonding position, and are connected via a conductive metal layer. Thus, it is possible to avoid the abnormity in bonding due to difference in thickness and offset between metal layers, thus reducing poor wiring due to abnormity in bonding and improving quality of products.

### RELATED APPLICATIONS

The present application claims the benefit of Chinese Patent Application No. 201310712539.5, filed Dec. 20, 2013, the entire disclosure of which is incorporated herein by reference.

### FIELD OF THE INVENTION

The present invention relates to the field of display technology, and particularly to an array substrate, a method for fabricating the same, and a display apparatus.

### BACKGROUND ART

During design and process of an array substrate, an integrated circuit (i.e., IC) plays important role for electrode wirings and printed circuit boards, (i.e., PCB), especially for connections between bonding pads on the array substrate and the PCB.

A large size display product generally comprises gate electrode pads (i.e., Gate Pad) and source/drain layer pads (i.e., S/D Pad). Nevertheless, a small size (7 inches or less) display product generally comprises only one pad. In the small size display product, the gate electrode layer usually adopts a GOA (gate driver on array) technique and IC bonding is not performed. Alternatively, the gate electrode layer adopts a COG (chip on glass) technique, in which an IC or a chip with the IC is directly fabricated on a glass substrate, and the conduction between the IC and the glass substrate is realized by ACF glue (anisotropic conductive film, also an anisotropic conductive adhesive). Currently, in the small size display product, the pad is generally designed to have double-layer wirings, which is space-saving.

There are drawbacks in the design of double-layer wirings. Namely, the difference between thicknesses of layers will influence the effect of bonding. Besides, the offset between wirings in different layers due to process fluctuations will influence the effect of bonding. In such a case, the bonding apparatus will issue a registration alarm, and abnormity in bonding will occur in a serious case.

### SUMMARY

### Technical Problem to be Solved

The present invention intends to solve the problem of preventing the phenomenon of abnormity in bonding due to pad.

### Technical Solutions

In order to solve the above-mentioned technical problem, the present invention provides an array substrate. The array substrate is provided with a plurality of signal lines in a peripheral area. At least two adhesion layers of different thicknesses are provided at positions of each signal line where the signal lines are designed for connecting with a driving IC chip, and the adhesion layers are electrically connected via a conductive metal layer.

Further, each adhesion layer is made from a metallic material.

Further, two adhesion layers are provided, one of the adhesion layers is formed in the same layer and made from the same material as a source/drain metal layer on the array substrate, and the other adhesion layer is formed in the same layer and made from the same material as a gate electrode layer on the array substrate.

Further, the conductive metal layer is formed in the same layer as a transparent conductive layer in the array substrate.

Further, the conductive metal layer is provided with openings for leading output terminals of the signal lines to a surface of the array substrate so as to be designed for connecting with the driving IC chip.

Further, the plurality of signal lines are divided into at least two layers, and adhesion layers provided between each layer of signal lines at positions where the signal lines are designed for connecting with driving IC chip do not overlap with each other.

In order to solve the above problem, the present invention further provides a method for fabricating a display apparatus, comprising steps of: forming a pattern comprising a plurality of signal lines in a peripheral area of the array substrate by a first patterning process; forming a pattern comprising at least two adhesion layers of different thicknesses at positions of each signal line which is designed for connecting with a driving IC chip by a second patterning process; and forming a pattern comprising a conductive metal layer by a third patterning process, the adhesion layers are electrically connected via the conductive metal layer.

Further, each adhesion layer is made from a metallic material.

Further, in the step of forming the pattern comprising two adhesion layers of different thicknesses by the second patterning process, one of the adhesion layers is formed in the same layer and made from the same material as a source/drain metal layer on the array substrate, and the other adhesion layer is formed in the same layer and made from the same material as a gate electrode layer on the array substrate.

Further, in the third patterning process, a conductive metal layer is formed in the same layer as a transparent conductive layer in the array substrate.

Further, after the third patterning process, the method further comprises: forming openings in the conductive metal layer, for leading output terminals of the signal lines to a surface of the array substrate so as to be designed for connecting with the driving IC chip.

Further, the pattern comprising the plurality of signal lines formed by the first patterning process are divided into at least two layers, and adhesion layers provided between each layer of signal lines at positions where the signal lines are designed for connecting with driving IC chip do not overlap with each other.

In order to solve the above-mentioned technical problem, the present invention further provides a display apparatus comprising a driving IC chip. The display apparatus further comprises the above-mentioned array substrate, and adhesion layers on the array substrate are connected with the driving IC chip via anisotropic conductive adhesive.

### Advantageous Effects

In embodiments of the present invention, an array substrate and a display apparatus are provided. A plurality of signal lines is provided in the peripheral area of the array substrate. At least two adhesion layers of different thicknesses are provided at positions of each signal line where the signal lines are designed for connecting with a driving IC chip. the adhesion layers are electrically connected via a conductive metal layer. According to the present invention, the adhesion layer is designed to have at least two adhesion layers, instead of a single layer in the prior art. Namely, two adhesion layers with different thicknesses are provided at a bonding position, and are connected via a conductive metal layer. In this manner, it is possible to avoid the abnormity in bonding due to difference in thickness and offset between metal layers, thus reducing poor wiring due to abnormity in bonding and improving quality of products. At the same time, the present invention further provides a display apparatus based on the above-mentioned array substrate, wherein adhesion layers on the array substrate are connected with the driving IC chip via anisotropic conductive adhesive.

### BRIEF DESCRIPTION OF DRAWINGS

FIG. 1 is a cross-sectional view illustrating a display apparatus in the prior art;

FIG. 2 is a partially exploded view at the position of pad after IC bonding in the prior art;

FIG. 3 is a cross-sectional view illustrating the structure of FIG. 2 in A-A′ direction;

FIG. 4 is a cross-sectional view illustrating the structure of FIG. 2 in B-B′ direction;

FIG. 5 is a partially exploded view illustrating a bonding pad after IC bonding in a first embodiment of the present invention;

FIG. 6 is a cross-sectional view illustrating the structure of FIG. 5 in C-C′ direction;

FIG. 7 is a cross-sectional view illustrating the structure of FIG. 5 in D-D′ direction; and

FIG. 8 is a flow chart illustrating a method for fabricating an array substrate in a second embodiment of the present invention.

### DETAILED DESCRIPTION OF EMBODIMENTS

The present disclosure will be elucidated hereinafter in details with reference to the accompanying drawings and embodiments. Apparently, these embodiments only constitute some embodiments of the present disclosure. The scope of the present disclosure is by no means limited to embodiments as set forth herein.

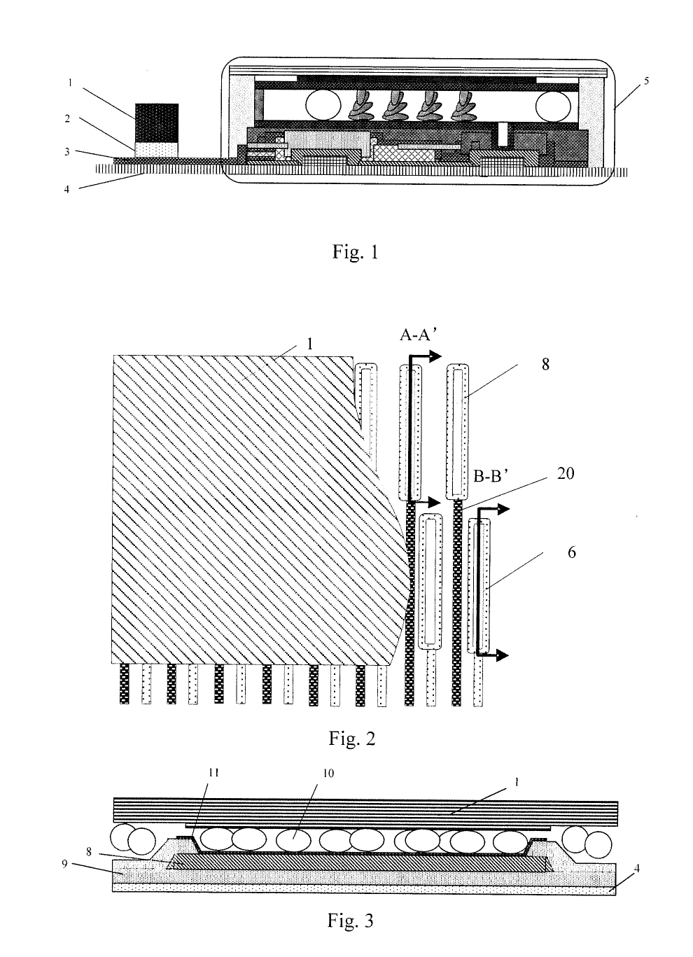

The position relationship among bonding pads, a driving IC, and an array substrate in the art is shown FIG. 1. Specifically, FIG. 1 is a cross-sectional view showing bonding pads in an IC. In the peripheral area of an array substrate 4, there is provided with bonding pad 3. IC 1 is electrically with bonding pads 3 via ACF 2. In a small size display product, wirings are formed into two layers in the peripheral area to save space. As shown in FIG. 2, the signal line 20 is divided into two layers of A-A′ and B-B′. These two layers of the signal line 20 are provided with adhesion layers 6, 8 at positions where they are connected with the driving IC 1, and the driving IC 1 is electrically with the adhesion layers 6, 8 via ACF 2.

Also shown in the right part of FIG. 1 is a cross-sectional view for a display area of the array substrate in the liquid crystal display panel, namely a frame indicated by a reference numeral 5. This corresponds to the array substrate, the color film substrate, and liquid crystal filled therebetween in the prior art, which is known in the art and thus is not repeated herein for simplicity.

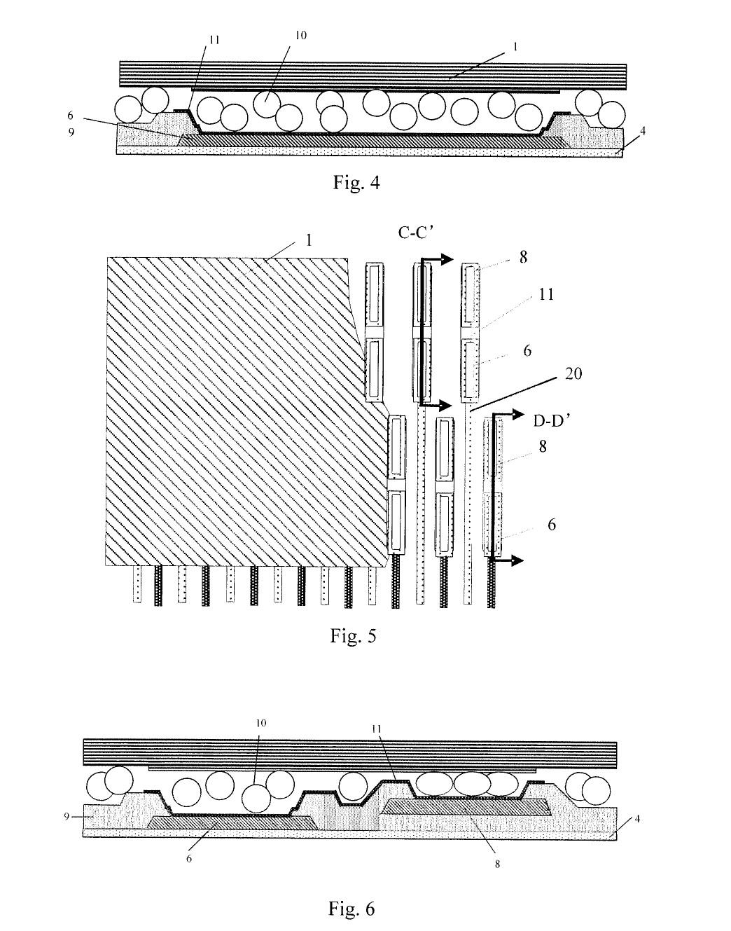

As shown in FIG. 2, the signal line 20 is arranged at a peripheral area of the array substrate 4, and is connected with the driving IC 1 via the bonding pad 3 and ACF 2. Conductive gold balls are doped in a glue to form ACF 2 for providing the function of anisotropic conduction. The outer surface of gold balls is an insulating layer, which will be destroyed when gold balls are compressed to deform. Therefore, the gold balls are conductive only when they are compressed to deform to a certain extent. A cross-sectional view taken along A-A′ in FIG. 2 is shown in FIG. 3, and a cross-sectional view taken along B-B′ in FIG. 2 is shown in FIG. 4. The following reference numerals are used in FIGS. 3-4: 1, driving IC; 4, array substrate; 6, adhesion layer which is formed in the same layer as the gate electrode layer (G layer); 8, adhesion layer which is formed in the same layer as the source/drain metal layer (S/D layer); 9, insulating layer; 10, conductive balls; and 11, conductive metal layer. As shown in FIG. 3, the insulating layer 9 is formed on the array substrate 4, the adhesion layer 8 is formed on the insulating layer 9 in the same layer as the S/D layer in the display area, and the insulating layer 9 is further formed on the adhesion layer 8. The insulating layer on the adhesion layer 8 is partially etched away, and the conductive metal layer 11 is formed over the insulating layer 9 in this area. As shown in FIG. 4, the adhesion layer 6 is formed on the array substrate 4 by a one-time patterning process and formed in the same layer as the G layer. The insulating layer 9 is further formed on the adhesion layer 6 and formed in the same layer as the G layer. Also, the insulating layer 9 formed on the adhesion layer 6 and formed in the same layer as the G layer is partially etched away. A metal layer is deposited on the remaining insulating layer 9 as the conductive metal layer 11. The conductive metal layer 11 is partially removed by etching. The conductive metal layer 11 remains in a region over the adhesion layer 6, a region over the insulating layer 9, and a region at edges of the insulating layer 9. Finally, conductive balls 10 are arranged between the driving IC 1 and the conductive metal layer 11, and the conductive metal layer 11 is connected with a signal line (not shown in FIGS. 3-4). The conductive balls 10 have an insulating layer at their outer layer and gold balls at the core. These conductive balls 10 are conductive only when they are compressed to deform so that the outer insulating layer is destroyed. The difference between FIGS. 3-4 follows. In FIG. 3, before the adhesion layer 8 is formed in the same layer as the S/D layer, an insulating layer 9 is further formed. As a result, the distance between the driving IC 1 and the adhesion layer 8 is smaller, so that conductive balls are compressed to provide better conductive properties.

The following conclusion is apparent from FIG. 3 and FIG. 4. In the case of FIG. 3 in which the adhesion layer 8 and the S/D layer in the display area are formed in the same layer, the conductive balls are compressed to deform. This enables excellent conduction between the driving IC 1 and the conductive metal layer 11 under the conductive balls, thus realizing excellent bonding. However, in the case of FIG. 4 in which the adhesion layer 6 and the G layer on the array substrate 4 are formed in the same layer, the conductive balls are not compressed to deform. This can not facilitate good conduction between the driving IC 1 and the conductive metal layer 11 under the conductive balls, thus leading to poor bonding. Two adhesion layers 8, 6 in FIG. 3 and FIG. 4 form two pads of different thicknesses, respectively. These pads are electrically connected with the driving IC via the conductive balls and the conductive metal layer. Further, for purpose of decreasing resistivity and cost, the G layer and the S/D layer are generally made from different metallic materials with different thicknesses. As a result, the bonding pad which is formed in the same layer as the G layer and the bonding pad which is formed in the same layer as the S/D layer have a difference in thickness, which influences the success rate of bonding. In addition, due to process fluctuations like offset between the G layer and the S/D layer during exposure, misalignment between bonding pads in the bonding area occurs, which will lead to abnormity in bonding.

### First Embodiment

Based on the foregoing, in the first embodiment of the present invention, there is provided an array substrate. The array substrate is provided with a plurality of signal lines 20 at the peripheral area. At least two adhesion layers 6, 8 of different thicknesses are provided at positions of each signal line 20 where the signal lines are designed for connecting with a driving IC chip. These adhesion layers are electrically connected via a conductive metal layer 11.

For example, the conductive metal layer 11 can be formed in the same layer as a transparent conductive layer in the array substrate. The transparent conductive layer can be made from a material like Indium Tin Oxide (ITO), Indium Zinc Oxide (IZO), or other transparent conductive materials. The transparent conductive layer can be a pixel electrode layer or a common electrode layer in the array substrate.

Each adhesion layer can be made from a metallic material. Specifically, both adhesion layers 6, 8 are metal layers.

Preferably, in the present embodiment, there are two adhesion layers. One of the adhesion layers 8 is formed in the same layer and made from the same material as the S/D layer on the array substrate. The other adhesion layer 6 is formed in the same layer and made from the same material as the G layer on the array substrate.

Preferably, in the present embodiment, the conductive metal layer 11 is provided with openings for leading output terminals of the signal lines 20 to a surface of the array substrate so as to be designed for connecting with the driving IC chip.

Preferably, in the present embodiment, the plurality of signal lines 20 is divided into at least two layers. In FIG. 5, two layers of signal lines are indicated with different fillings. Adhesion layers provided between each layer of signal lines at positions where the signal lines are designed for connecting with driving IC chip do not overlap with each other.

FIG. 5 is a partially exploded view illustrating the above-mentioned bonding pad after IC bonding, which comprises the conductive metal layer 11, the adhesion layer 6 which is formed in the same layer as the G layer, and the adhesion layer 8 which is formed in the same layer as the S/D layer. The conductive metal layer 11 can be made from a transparent metal oxide like ITO.

An improvement in the present invention lies in that the pad comprises two adhesion layers with different thicknesses, i.e., the adhesion layer 6 formed in the same layer as the G layer and the adhesion layer 8 formed in the same layer as the S/D layer. In other words, in the present first embodiment, a pad comprises two parts, i.e., a first pad and a second pad. These two pads are located in the same layer signal line and are connected via the conductive metal layer 11, so as to avoid the difference in thicknesses due to the presence of pads.

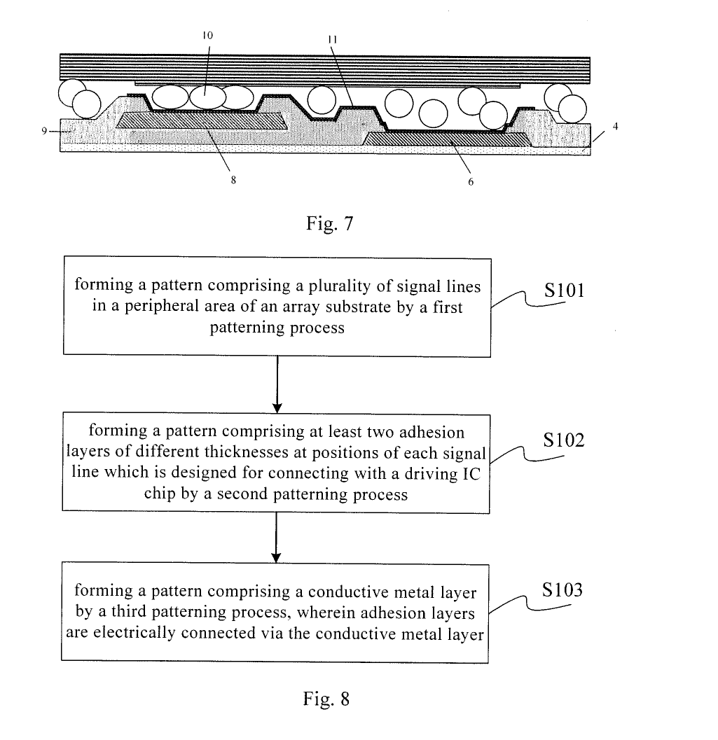

Further, the cross-sectional view taken along C-C′ in FIG. 5 is shown in FIG. 6, and the cross-sectional view taken along D-D′ in FIG. 5 is shown in FIG. 7. In both FIG. 6 and FIG. 7, the driving IC 1, the array substrate 4, the adhesion layer 6 formed in the same layer as the G layer, the adhesion layer 8 formed in the same layer as the S/D layer, the insulating layer 9, the conductive ball 10, and the conductive metal layer 11 are shown. As shown in FIG. 6, the adhesion layer 6 is formed on the array substrate 4 and in the same layer as the G layer on the array substrate 4 by a one-time patterning process, the insulating layer 9 is then formed on the adhesion layer 6 formed in the same layer as the G layer, the insulating layer 9 on the adhesion layer 6 is partially etched away, and a portion of the insulating layer 9 remains. Then, the adhesion layer 8 is formed in the same layer as the S/D layer, and the conductive metal layer 11 is formed in the same layer as the transparent conductive layer on the array substrate. The conductive metal layer 11 comprises a portion over the adhesion layer 6 and a portion over the adhesion layer 8. Finally, the conductive balls 10 are arranged between the driving IC 1 and the conductive metal layer 11.

Of course, the conductive metal layer 11 can be formed by a separate process. For example, the conductive metal layer 11 can be formed by depositing a metal layer on the adhesion layer 6 and the adhesion layer 8, and removing the metal layer by etching, so that the metal layer remains only in a region over the adhesion layers 6, 8, a region over the insulating layer 9, and a region at the edge of the insulating layer 9.

As shown in FIG. 6, in one of the signal lines, conductive balls 10 over the adhesion layer 6 formed in the same layer as the G layer are not compressed, while conductive balls 10 over the adhesion layer 8 formed in the same layer as the S/D layer are compressed. As shown in FIG. 7, in the other signal line, conductive balls 10 over the adhesion layer 6 formed in the same layer as the G layer are not compressed, while conductive balls over the adhesion layer 8 formed in the same layer as the S/D layer are compressed. Of course, there are many variations. For example, conductive balls over both adhesion layers of each signal line can be compressed. Alternatively, conductive balls over any adhesion layer in one of the signal lines can be compressed. In a word, as compared with the prior art, each layer of signal line or the pad on each signal line comprises two adhesion layers 6, 8 of different thicknesses. As a result, electrical connection with the driving IC 1 is always guaranteed on at least one of the adhesion layers 6, 8 via the conductive metal layer 11 and conductive balls 10. Thereby, it is possible to avoid poor bonding due to offset between metal layers when a signal line only comprises a metal layer of a certain thickness.

Thus, in the present embodiment, in contrast with the existing pad with only one pad, the bonding pad is designed to have two metal pads which are formed in the same layer as the G layer and the S/D layer respectively, and two metal pads are connected with a conductive metal layer. In this way, it is possible to avoid abnormity in bonding difference in thickness and offset between metal layers, thus reducing abnormity in bonding due to poor wiring.

### Second Embodiment

The present invention further provides a method for fabricating a display apparatus. The flow chart for this method is shown in FIG. 8. The method comprises the following steps.

In Step S101, a pattern comprising a plurality of signal lines is formed in a peripheral area of the array substrate by a first patterning process.

In Step S102, a pattern comprising at least two adhesion layers of different thicknesses is formed at positions of each signal line for connecting with a driving IC chip by a second patterning process.

In Step S103, a pattern comprising a conductive metal layer is formed by a third patterning process, and the adhesion layers are electrically connected via a conductive metal layer.

Preferably, in the present embodiment, each adhesion layer can be made from a metallic material.

Preferably, in the present embodiment, in the step of forming the pattern comprising two adhesion layers with different thicknesses by the second patterning process, one of the adhesion layers is formed in the same layer and made from the same material as a S/D layer on the array substrate, and the other adhesion layer is formed in the same layer and made from the same material as a G layer on the array substrate.

Preferably, in the present embodiment, in the third patterning process, a conductive metal layer is formed in the same layer as a transparent conductive layer in the array substrate.

Preferably, in the present embodiment, after the third patterning process, the method further comprises: forming openings in the conductive metal layer, for leading output terminals of the signal lines to a surface of the array substrate so as to be designed for connecting with the driving IC chip.

Preferably, in the present embodiment, the pattern comprising the plurality of signal lines formed by the first patterning process is divided into at least two layers, and adhesion layers provided between each layer of signal lines at positions where the signal lines are designed for connecting with driving IC chip do not overlap with each other.

Thus, in the present embodiment, in contrast with the existing pad with only one pad, the bonding pad is designed to have two metal pads which are formed in the same layer as the G layer and the S/D layer respectively, and two metal pads are connected with a conductive metal layer. In this way, it is possible to avoid abnormity in bonding difference in thickness and offset between metal layers, thus reducing abnormity in bonding due to poor wiring.

### Third Embodiment

The third embodiment of the present invention further provides a display apparatus. The display apparatus comprises a driving IC chip, and an array substrate provided by preceding embodiments of the present invention. Adhesion layers on the array substrate are connected with the driving IC chip via anisotropic conductive adhesive.

Although the present disclosure has been described above with reference to specific embodiments, it should be understood that the limitations of the described embodiments are merely for illustrative purpose and by no means limiting. Instead, the scope of the disclosure is defined by the appended claims rather than by the description, and all variations that fall within the range of the claims are intended to be embraced therein. Thus, other embodiments than the specific ones described above are equally possible within the scope of these appended claims.

1. An array substrate, provided with a plurality of signal lines in a peripheral area, characterized in that, at least two adhesion layers of different thicknesses are provided at positions of each signal line where the signal lines are designed for connecting with a driving IC chip, and said adhesion layers are electrically connected via a conductive metal layer.

2. The array substrate of claim 1, characterized in that, each adhesion layer is made from a metallic material.

3. The array substrate of claim 1, characterized in that, two adhesion layers are provided, one of the adhesion layers is formed in the same layer and made from the same material as a source/drain metal layer on the array substrate, and the other adhesion layer is formed in the same layer and made from the same material as a gate electrode layer on the array substrate.

4. The array substrate of claim 3, characterized in that, said conductive metal layer is formed in the same layer as a transparent conductive layer in said array substrate.

5. The array substrate of claim 1, characterized in that, said conductive metal layer is provided with openings for leading output terminals of the signal lines to a surface of the array substrate so as to be designed for connecting with the driving IC chip.

6. The array substrate of claim 1, characterized in that, said plurality of signal lines are divided into at least two layers, and adhesion layers provided between each layer of signal lines at positions where the signal lines are designed for connecting with driving IC chip do not overlap with each other.

7. A method for fabricating an array substrate, characterized in that, said method comprises steps of:
forming a pattern comprising a plurality of signal lines in a peripheral area of said array substrate by a first patterning process;
forming a pattern comprising at least two adhesion layers of different thicknesses at positions of each signal line which is designed for connecting with a driving IC chip by a second patterning process; and
forming a pattern comprising a conductive metal layer by a third patterning process, wherein said adhesion layers are electrically connected via said conductive metal layer.

8. The method of claim 7, characterized in that, each adhesion layer is made from a metallic material.

9. The method of claim 7, characterized in that, in the step of forming the pattern comprising two adhesion layers of different thicknesses by the second patterning process, one of the adhesion layers is formed in the same layer and made from the same material as a source/drain metal layer on the array substrate, and the other adhesion layer is formed in the same layer and made from the same material as a gate electrode layer on the array substrate.

10. The method of claim 7, characterized in that, in said third patterning process, a conductive metal layer is formed in the same layer as a transparent conductive layer in said array substrate.

11. The method of claim 7, characterized in that, after said third patterning process, the method further comprises: forming openings in said conductive metal layer, for leading output terminals of the signal lines to a surface of the array substrate so as to be designed for connecting with the driving IC chip.

12. The method of claim 7, characterized in that, the pattern comprising the plurality of signal lines formed by said first patterning process are divided into at least two layers, and adhesion layers provided between each layer of signal lines at positions where the signal lines are designed for connecting with driving IC chip do not overlap with each other.

13. A display apparatus, comprising a driving IC chip, characterized in that, the display apparatus further comprises the array substrate of any one of claim 1, and adhesion layers on said array substrate are connected with said driving IC chip via anisotropic conductive adhesive.

14. A display apparatus, comprising a driving IC chip, characterized in that, the display apparatus further comprises the array substrate of any one of claim 2, and adhesion layers on said array substrate are connected with said driving IC chip via anisotropic conductive adhesive.

15. A display apparatus, comprising a driving IC chip, characterized in that, the display apparatus further comprises the array substrate of any one of claim 3, and adhesion layers on said array substrate are connected with said driving IC chip via anisotropic conductive adhesive.

16. A display apparatus, comprising a driving IC chip, characterized in that, the display apparatus further comprises the array substrate of any one of claim 4, and adhesion layers on said array substrate are connected with said driving IC chip via anisotropic conductive adhesive.

17. A display apparatus, comprising a driving IC chip, characterized in that, the display apparatus further comprises the array substrate of any one of claim 5, and adhesion layers on said array substrate are connected with said driving IC chip via anisotropic conductive adhesive.

18. A display apparatus, comprising a driving IC chip, characterized in that, the display apparatus further comprises the array substrate of any one of claim 6, and adhesion layers on said array substrate are connected with said driving IC chip via anisotropic conductive adhesive.
